(19) United States
(12) Patent Application Publication
(10) Pub. No.: US 2025/0160024 A1
(43) Pub. Date: May 15, 2025

(54) IMAGE SENSING DEVICE

(71) Applicant: SK hynix Inc., Icheon-si (KR)

(72) Inventor: Sung Wook CHO, Icheon-si (KR)

(21) Appl. No.: 18/628,378

(22) Filed: Apr. 5, 2024

(30) Foreign Application Priority Data
Nov. 14, 2023 (KR) 10-2023-0156862

(51) Int. Cl. H01L 27/146

(52) U.S. Cl. CPC H10F 39/807; H10F 39/8053; H10F 39/8063

(57) ABSTRACT

In an embodiment, an image sensing device includes a pixel array including a plurality of unit pixels, wherein each of the unit pixels comprises a plurality of sub-pixels, wherein a first isolation region is formed in an edge region of the plurality of sub-pixels, wherein a second isolation region is formed from the first isolation region toward a central portion of each of the sub-pixels, wherein the second isolation region comprises: a first inner isolation region protruding from one region of the first isolation region toward the central portion of the sub-pixel; and a second inner isolation region aligned with the first inner isolation region and protruding from another region of the first isolation region toward the central portion of the sub-pixel, wherein a third isolation region is formed in a direction orthogonal to a direction in which the first inner isolation region and the second inner isolation region.

### PRIORITY CLAIM AND CROSS REFERENCE TO RELATED APPLICATION

This patent document claims the priority and benefits of Korean Patent Application No. 10-2023-0156862, filed on Nov. 14, 2023, which is incorporated by reference in its entirety as part of the disclosure of this patent document.

### TECHNICAL FIELD

Various embodiments of the disclosed technology relate to an image sensing device.

### BACKGROUND

An image sensing device refers to a semiconductor device that captures optical images and converts them into electrical signals. With the development of automobile, medical, computer and telecommunication industries, the demand for high-performance image sensing devices is increasing in various devices such as smart phones, digital cameras, game devices, Internet of Things, robots, security cameras, and medical micro-cameras.

The most common types of image sensing devices are charge coupled device (CCD) image sensing devices and complementary metal oxide semiconductor (CMOS) image sensing devices.

### SUMMARY

The disclosed technology can be implemented in some embodiments to provide an image sensing device capable of improving a Gr/Gb signal difference while minimizing an optical loss by forming a light-scattering region.

In an embodiment, an image sensing device may include a pixel array including a plurality of unit pixels, wherein each of the unit pixels comprises: a plurality of sub-pixels; wherein a first isolation region may be formed in an edge region of the plurality of sub-pixels; wherein a second isolation region may be formed from the first isolation region toward a central portion of each of the sub-pixels, wherein the second isolation region comprises: a first inner isolation region protruding from one region of the first isolation region toward the central portion of the sub-pixel; and a second inner isolation region aligned with the first inner isolation region and protruding from another region of the first isolation region toward the central portion of the sub-pixel; and wherein a third isolation region is formed in a direction orthogonal to a direction in which the first inner isolation region and the second inner isolation region.

In an example, each of the sub-pixels comprises: the first isolation region; the second isolation region comprising the first inner isolation region and the second inner isolation region; an isolation layer formed over the first inner isolation region and the second inner isolation region; the third isolation region formed below the isolation layer; a color filter formed over the isolation layer; and a microlens formed over the color filter.

In an example, the second inner isolation region is formed at a position spaced apart by a certain distance from the first inner isolation region.

In an example, the third isolation region is formed in a direction crossing between the first inner isolation region and the second inner isolation region, from one side of the first isolation region perpendicular to the first inner isolation region or the second inner isolation region.

In an example, the third isolation region comprises at least one of an oxide, a nitride, or an oxynitride.

In an example, the third isolation region comprises a material different from a material of the second isolation region.

In an example, the second isolation region comprises a material having a higher refractive index than a refractive index of silicon.

In an example, the second isolation region comprises polysilicon.

In an example, the third isolation region comprises a material having a lower refractive index than a refractive index of silicon.

In an example, a depth of the third isolation region is smaller than a depth of the second isolation region.

In an example, the third isolation region is in contact with the second isolation region.

In an example, the third isolation region is spaced apart from the second isolation region.

In an embodiment, an image sensing device may include a pixel array including a plurality of u nit pixels, wherein each of the unit pixels comprises: a first sub-pixel comprising a green color filter; a second sub-pixel comprising a red color filter; a third sub-pixel comprising a blue color filter; wherein a first isolation region may be formed in an edge region of the first sub-pixel, wherein a fourth isolation region may be formed in an edge region of the second sub-pixel, wherein a second isolation region may be formed from the first isolation region toward a central portion of the first sub-pixel, wherein a fifth isolation region may be formed to protrude from the fourth isolation region in a direction perpendicular to a direction in which the second isolation region is formed, wherein the second isolation region comprises: a first inner isolation region protruding from one region of the first isolation region toward the central portion of the first sub-pixel; and a second inner isolation region aligned with the first inner isolation region and protruding from another region of the first isolation region toward the central portion of the first sub-pixel, wherein the fifth isolation region comprises: a third inner isolation region protruding from one region of the fourth isolation region toward a central portion of the second sub-pixel; and a fourth inner isolation region aligned with the third inner isolation region and protruding from another region of the fourth isolation region toward the central portion of the second sub-pixel, wherein a third isolation region may be formed in a direction orthogonal to a direction in which a first inner isolation region and the second inner isolation region are arranged; and wherein a sixth isolation region may be formed in a direction orthogonal to a direction in which the third inner isolation region and the fourth inner isolation region are arranged.

In an example, wherein the first sub-pixel comprises: the first isolation region; the second isolation region comprising the first inner isolation region and the second inner isolation region; an isolation layer formed over the first isolation region and the second isolation region; the third isolation region formed below the isolation layer; the green color filter formed over the isolation layer; and a microlens formed over the green color filter.

In an example, the first inner isolation region is formed at a position spaced apart by a certain distance from the second inner isolation region.

In an example, the third isolation region is formed in a direction crossing between the first inner isolation region and the second inner isolation region, from one side of the first isolation region perpendicular to the first inner isolation region or the second inner isolation region.
In an example, the third isolation region comprises at least one of an oxide, a nitride, or an oxynitride.

In an example, the third inner isolation region is formed at a position spaced apart by a certain distance from the fourth inner isolation region.

In an example, the sixth isolation region is formed in a direction crossing between the third inner isolation region and the fourth inner isolation region, from one side of the fourth isolation region perpendicular to the third inner isolation region or the fourth inner isolation region.

In an example, wherein a seventh isolation region may be formed in an edge region of the third sub-pixel, wherein an eighth isolation region may be formed to protrude from the seventh isolation region in a direction perpendicular to the direction in which the second isolation region is formed, wherein the eighth isolation region comprises: a fifth inner isolation region protruding from one region of the seventh isolation region toward a central portion of the third sub-pixel; and a sixth inner isolation region aligned with the fifth inner isolation region and protruding from another region of the seventh isolation region toward the central portion of the third sub-pixel, and wherein a ninth isolation region may be formed in a direction orthogonal to a direction in which the fifth inner isolation region and the sixth inner isolation region are arranged.

### BRIEF DESCRIPTION OF THE DRAWINGS

FIG. 1 is a block diagram of an image sensing device based on an embodiment.

FIG. 2 is a view for describing a pixel array based on an embodiment.

FIG. 3 is a view for describing a first sub-pixel of a pixel array based on an embodiment.

FIG. 4 is a cross-sectional view taken along line A-A′ of a first sub-pixel of FIG. 3.

FIG. 5 is a cross-sectional view taken along line B-B′ of a first sub-pixel of FIG. 3.

FIG. 6 is a view for describing a second sub-pixel of a pixel array based on an embodiment.

FIG. 7 is a cross-sectional view taken along line C-C′ of a second sub-pixel of FIG. 6.

FIG. 8 is a view for describing a third sub-pixel of a pixel array based on an embodiment.

FIG. 9 is a cross-sectional view taken along line D-D′ of a third sub-pixel of FIG. 8.

### DETAILED DESCRIPTION

Features, and certain advantages in connection with specific implementations of the disclosed technology disclosed in this patent document are described by example embodiments with reference to the accompanying drawings.

The disclosed technology can be implemented in some embodiments to provide an image sensing device capable of improving a signal difference (Gr/Gb) between a Gr pixel and a Gb pixel. In some implementations, the signal difference (Gr/Gb) indicates a signal difference between green pixels in a row of blue (Gb) to green pixels in a row of red (Gr).

In the case of a dual photodiode (2PD) type image sensing device, the light incident on the microlens is scattered by a deep trench isolation region (DTI) and passes through a wall surface of a neighboring pixel, serving as a crosstalk.

In the case of red wavelengths, the amount of penetration into neighboring pixels is greater than that of blue or green wavelengths, so the signal of a Gr pixel or a Gb pixel may increase depending on the 2PD direction of a red pixel.

Depending on a 2PD direction of the red pixel, a Gr/Gb signal difference may have a value is less than or greater than 1, causing deterioration. In some implementations, by forming a light-scattering region in a direction crossing (or extending) between inner isolation regions, an output signal difference (Gr/Gb) between a Gr pixel and a Gb pixel of a Bayer pattern may be improved while minimizing light loss. That is, by forming a light-scattering region in a direction crossing (or extending) between the inner isolation regions, a difference between Gr and Gb can be minimized, so that a Gr/Gb signal difference has a value close to 1.

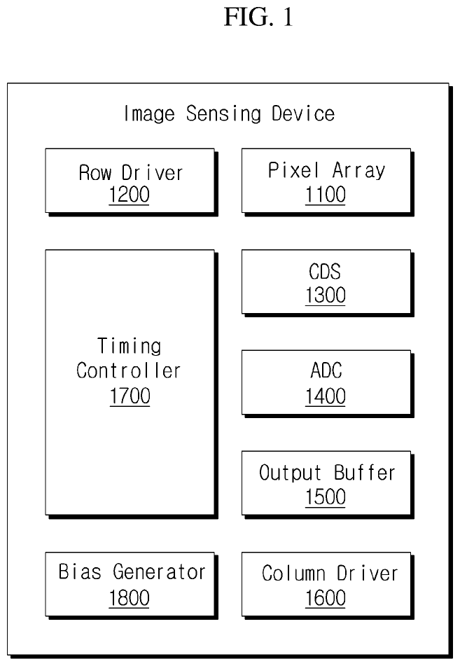

FIG. 1 is a block diagram of an image sensing device based on an embodiment.

Referring to FIG. 1, the image sensing device based on an embodiment may include a pixel array 1100, a row driver 1200, a correlated double sampler (CDS) 1300, an analog-digital converter (ADC) 1400, an output buffer 1500, a column driver 1600, a timing controller 1700, and a bias generator 1800. The components of the image sensing device illustrated in FIG. 1 are discussed by way of example only, and the disclosed technology is not limited to what is illustrated in FIG. 1.

The pixel array 1100 may include a plurality of pixels arranged in a plurality of rows and a plurality of columns. In one embodiment, the plurality of pixels can be arranged in a two-dimensional pixel array including rows and columns. In another example, the plurality of unit imaging pixels can be arranged in a three-dimensional pixel array. The plurality of pixels may detect incident light to capture images carried by the incident light by converting an optical signal or the incident light into an electrical signal on a unit pixel basis or on a pixel group basis and the pixels in a pixel group share at least certain internal circuitry. Such generated electrical signals by different pixels or by different pixel groups collectively represent images carried in the incident light. The pixel array 1100 may receive driving signals, including a row selection signal, a pixel reset signal and a transmission signal, from the row driver 1200. Upon receiving the driving signal, corresponding pixels in the pixel array 1100 may be activated to perform operations corresponding to the row selection signal, the pixel reset signal, and the transmission signal.

The row driver 1200 may activate the pixel array 1100 to perform certain operations on the pixels in the corresponding row based on commands and control signals provided by the timing controller 1700. In one embodiment, the row driver 1200 may select at least one pixel arranged in at least one row of the pixel array 1100. The row driver 1200 may generate a row selection signal to select at least one row among the plurality of rows. The row driver 1200 may sequentially enable the pixel reset signal and the transmission signal for the pixels corresponding to the at least one selected row. Thus, a reference signal and an image signal, which are analog signals generated by each of the pixels of the selected row, may be sequentially transferred to the CDS 1300. Here, the reference signal may be an electrical signal that is provided to the CDS 1300 when a sensing node of a pixel (e.g., floating diffusion node) is reset, and the image signal may be an electrical signal that is provided to the CDS 1300 when photocharges generated by the pixel are accumulated in the sensing node. A reference signal representing reset noise inherent in a pixel and an image signal representing intensity of incident light may be collectively referred to as a pixel signal.

CMOS image sensors may use the correlated double sampling (CDS) to remove undesired offset values of pixels known as the fixed pattern noise by sampling a pixel signal twice to remove the difference between these two samples. In some embodiments, the correlated double sampling (CDS) may remove the undesired offset value of pixels by comparing pixel output voltages obtained before and after photocharges generated by the unit pixel in responding to incident light are accumulated in the sensing node so that only pixel output voltages based on the incident light can be measured. In one embodiment, the CDS 1300 may sequentially sample and hold the reference signal and the image signal, which are provided to each of a plurality of column lines from the pixel array 1100. That is, the CDS 1300 may sample and hold the reference signal and the image signal which correspond to each of the columns of the pixel array 1100.

The CDS 1300 may transfer the reference signal and the image signal of each of the columns as a correlate double sampling signal to the ADC 1400 based on control signals from the timing controller 1700.

The ADC 1400 is used to convert CDS signals into digital signals for each of the columns and output the digital signal. In one embodiment, the ADC 1400 may be implemented as a ramp-compare type ADC. The ramp-compare type ADC may include a comparator circuit for comparing the analog pixel signal with a ramp signal that ramps up or down over time, and a counter that counts until the ramp signal matches the analog pixel signal. In one embodiment, the ADC 1400 may convert the correlate double sampling signal generated by the CDS 1300 for each of the columns into a digital signal, and output the digital signal.

The ADC 1400 may include a plurality of column counters corresponding to each of the columns of the pixel array 1100. Each column of the pixel array 1100 is coupled to a column counter, and image data can be generated by converting the correlate double sampling signals corresponding to each of the columns into digital signals using the column counters. In another embodiment, the ADC 1400 may include a global counter to convert the correlate double sampling signals corresponding to each of the columns into digital signals using a global code provided from the global counter.

The output buffer 1500 may temporarily hold the column-based image data provided from the ADC 1400 to output the image data. The output buffer 1500 may temporarily store the image data output from the ADC 1400 based on control signals of the timing controller 1700. The output buffer 1500 may serve as an interface to compensate for data rate differences or transmission (or processing) rate differences between the image sensing device and other devices.

The column driver 1600 may select a column of the output buffer 1500 based on a control signal from the timing controller 1700, and sequentially output the image data, which are temporarily stored in the selected column of the output buffer 1500. In one embodiment, upon receiving an address signal from the timing controller 1700, the column driver 1600 may generate a column selection signal based on the address signal and select a column of the output buffer 1500, outputting the image data as an output signal from the selected column of the output buffer 1500.

The timing controller 1700 may control at least one of the row driver 1200, the CDS 1300, the ADC 1400, the output buffer 1500, the column driver 1600, or the bias generator 1800.

The timing controller 1700 may provide a clock signal required for the operations of the respective components of the image sensing device, a control signal for timing control, and address signals for selecting a row or column, a signal that controls a level of a bias voltage applied to the pixel array 1100, and the like to at least one of the row driver 1200, the CDS 1300, the ADC 1400, the output buffer 1500, the column driver 1600, or the bias generator 1800. In an embodiment of the present disclosure, the timing controller 1700 may include a logic control circuit, a phase lock loop (PLL) circuit, a timing control circuit, a communication interface circuit and others.

The bias generator 1800 may generate a bias voltage for suppressing a dark current generated in pixels of the pixel array 1100 and supply the generated bias voltage to the pixel array 1100.

The bias voltage may be determined during a wafer probe test of the image sensing device and stored in a one-time programmable (OTP) memory. For example, the bias voltage may be experimentally determined as a value capable of maximizing a dark current suppression effect while minimizing unnecessary power consumption without impairing performance of the image sensing device.

The bias generator 1800 may generate a voltage corresponding to the bias voltage stored in the OTP memory. In an embodiment, the OTP memory may be included in the image sensing device, and in particular, may be included in the bias generator 1800.

In an embodiment, the bias voltage may have one of a plurality of values.

For example, the plurality of values may respectively correspond to a plurality of operation modes of the image sensing device. The dark current generated at low light and the dark current generated at high light may be different from each other, and the bias voltage provided by the bias generator 1800 to effectively suppress the dark currents in each environment may vary depending on the mode.

In some implementations, the plurality of values may respectively correspond to a plurality of areas of the pixel array 1100. The dark current generated may be different from each other depending on the position of the pixel in the pixel array 1100, and the bias voltage provided by the bias generator 1800 to effectively suppress the dark current regardless of the position of the pixel may vary depending on the area.

The bias voltage may be a negative voltage having a negative sign, but the present disclosure is not limited thereto.

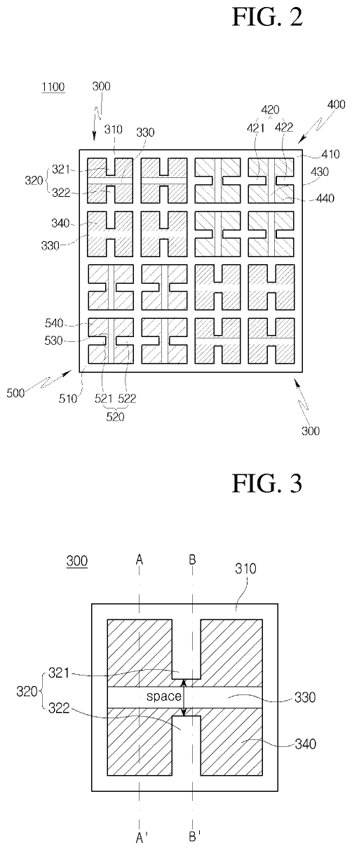

FIG. 2 is a view for describing the pixel array based on an embodiment. FIG. 3 is a view for describing a first sub-pixel of the pixel array based on an embodiment.

Referring to FIG. 2, the image sensing device based on an embodiment may be the image sensing device of a dual photodiode type (2PD).

In an embodiment, the pixel array 1100 may include a plurality of unit pixels (or unit image sensing pixels), and each unit pixel may include a first sub-pixel 300 including a green color filter to produce a first sub-pixel signal associated with detected light in the green color, a second sub-pixel 400 including a red color filter to produce a second sub-pixel signal associated with detected light in the red color, and a third sub-pixel 500 including a blue color filter to produce a third sub-pixel signal associated with detected light in the blue color. For example, each unit pixel may include a combination of two first sub-pixel 300, one second sub-pixel 400, and one third sub-pixel 500. The sub-pixel signals generated by the sub-pixels are associated with the unit pixel signal generated by the unit pixel in which the sub-pixels are located. In some implementations, the term “pixel” can be used to indicate an image sensing pixel or image sensor pixel, which is a light-sensing element in the image sensing device.

In some embodiments, each unit pixel may include four sub-pixels. In one example, each sub-pixel may include color filters of the same color. In one example, two photodiodes may be formed below each color filter.

Referring to FIGS. 2 and 3, a first isolation region 310 may be formed in an edge region (e.g., a boundary region between the first sub-pixels 300) of the first sub-pixel 300. The first isolation region 310 may be formed in a deep recess in the vertical direction to prevent a crosstalk among the neighboring first sub-pixels 300, and may be formed through a deep trench isolation (DTI) process.

The first isolation region 310 may include at least one of a silicon oxynitride (SiON) layer, a silicon oxide (SiO) layer, a silicon nitride (SiN) layer, or polysilicon (Poly Si).

A second isolation region 320 may be formed inside the first isolation region 310. The second isolation region 320 may be formed from the first isolation region 310 toward a central portion of the first sub-pixel 300.

The second isolation region 320 may be formed in a deep recess in the vertical direction to prevent crosstalk among neighboring photodiodes and may be formed through the deep trench isolation (DTI) process.

The second isolation region 320 may include the same material as that of the first isolation region 310.

The second isolation region 320 may include a material having a higher refractive index than that of silicon (Si).

The second isolation region 320 may include at least one of a silicon oxynitride (SiON) layer, a silicon oxide (SiO) layer, a silicon nitride (SiN) layer, or polysilicon (Poly Si).

In an embodiment, the second isolation region 320 may include a first inner isolation region 321, and a second inner isolation region 322.

The first inner isolation region 321 may protrude from one region of the first isolation region 310 toward the central portion of the first sub-pixel 300.

The second inner isolation region 322 may be aligned with the first inner isolation region 321 (e.g., formed on the same straight line as the first inner isolation region 321), and may protrude from another region of the first isolation region 310 (a region opposite to a region in which the first inner isolation region 321 is formed) toward the central portion of the first sub-pixel 300.

In an embodiment, the first inner isolation region 321 may be formed at a position spaced apart by a certain distance from the second inner isolation region 322.

A third isolation region 330 may be formed between the first inner isolation region 321 and the second inner isolation region 332.

The third isolation region 330 may be formed in a direction orthogonal to the direction in which the first inner isolation region 321 and the second inner isolation region 322 are arranged.

In some implementations, one end of the third isolation region 330 is connected to one side of the first isolation region 310, and the other end of the third isolation region 330 is connected to an opposite side of the one side of the first isolation region 310.

The third isolation region 330 may include a material different from a material of the second isolation region 320.

The third isolation region 330 may include a material having a lower refractive index than a refractive index of silicon (Si).

In an embodiment, the third isolation region 330 may include an oxide.

In an embodiment, the third isolation region 330 may include at least one of an oxide, a nitride, or an oxynitride.

The third isolation region 330 may have a depth different from a depth of the second isolation region 320.

The depth of the third isolation region 330 may be smaller than a depth of the second isolation region 320.

In an embodiment, an oxide layer (not illustrated) may be formed on a sidewall of the second isolation region 320. In one example, the third isolation region 330 may be in contact with the oxide layer (not illustrated) of the second isolation region 320. In another example, the third isolation region 330 may be spaced apart from the oxide layer (not illustrated) of the second isolation region 320.

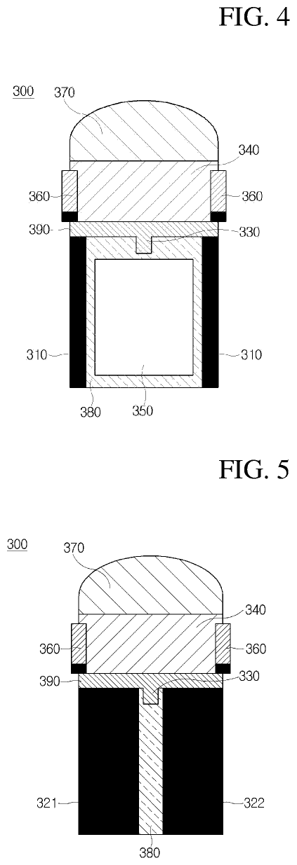

FIG. 4 is a cross-sectional view taken along line A-A′ of the first sub-pixel of FIG. 3. FIG. 5 is a cross-sectional view taken along line B-B′ of the first sub-pixel of FIG. 3.

Referring to FIGS. 4 and 5, the first sub-pixel 300 may include the first isolation region 310, the first inner isolation region 321, the second inner isolation region 322, the third isolation region 330, a green color filter 340, a photodiode 350, a filter layer isolation region 360, a microlens 370, a substrate 380, and an isolation layer 390.

The first isolation region 310 may be formed between neighboring first sub-pixels 300.

The first inner isolation region 321 and the second inner isolation region 322 may be formed below the isolation layer 390.

In an embodiment, the third isolation region 330 may be formed below the isolation layer 390, and may include a region in which at least one of an oxide, a nitride, or an oxynitride is formed (e.g., deposited) in a groove in an etched region of the substrate 380. In an embodiment, the third isolation region 330 may be formed with a thin thickness on a surface of the substrate 380.

In an embodiment, the third isolation region 330 may be formed in a direction crossing (or extending) between the first inner isolation region 321 and the second inner isolation region 322, from one side of the first isolation region 310 perpendicular to the first inner isolation region 321 or the second inner isolation region 322. In an embodiment, the first inner isolation region 321, the second inner isolation region 322, and the third isolation region 330 may form a cross structure.

Since the third isolation region 330 having a thin thickness is formed in the direction crossing (or extending) between the first inner isolation region 321 and the second inner isolation region 322, the scattered light may be dispersed in both directions (upward and downward, and left and right directions), rather than one direction (upward and downward, or left and right directions), and accordingly the output signal (Gr/Gb) differences between the Gr pixel and the Gb pixel of the Bayer pattern may be improved. In addition, the optical loss may be minimized and Gr/Gb signal differences may be improved compared to the pixel isolation region of a cross structure (DTI). In the case of the pixel isolation region of a cross structure (DTI), the optical loss may occur due to the optical absorption.

The green color filter 340 may be formed over the isolation layer 390. The green color filter 340 may filter and pass the visible light out of the incident light incident on the microlens 370, and may allow only the green light out of the visible light to path through.

The photodiode 350 may be formed in an inner region of the substrate 380 and may be formed below the third isolation region 330, and a n-type impurity region and a p-type impurity region may be vertically stacked in the photodiode 350. The n-type impurity region and the p-type impurity region may be formed through an ion injection process.

The filter layer isolation region 360 may be formed over the first isolation region 310.

The microlens 370 may be formed over the green color filter 340, and may serve to collect the incident light entered from the outside.

In an embodiment, the substrate 380 may include a silicon (Si) material in a single-crystalline state.

The isolation layer 390 may be formed over the first isolation region 310 and the second isolation region 320, and may include at least one of an oxide, a nitride, or an oxynitride.

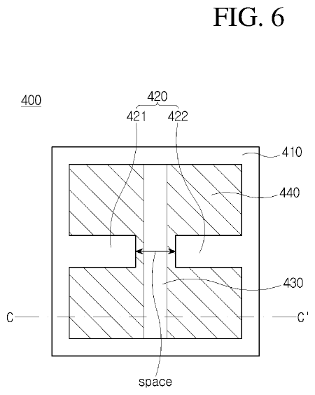

FIG. 6 is a view for describing the second sub-pixel of the pixel array based on an embodiment.

Referring to FIGS. 2 and 6, a fourth isolation region 410 may be formed in an edge region (a boundary region between the second sub-pixels 400) of the second sub-pixel 400. The fourth isolation region 410 may be formed in a deep recess in the vertical direction to prevent a crosstalk among neighboring sub-pixels and may be formed through the deep trench isolation (DTI) process.

The fourth isolation region 410 may include at least one of a silicon oxynitride (SiON) layer, a silicon oxide (SiO) layer, a silicon nitride (SiN) layer, or polysilicon (Poly Si).

A fifth isolation region 420 may be formed inside the fourth isolation region 410. The fifth isolation region 420 may be formed from the fourth isolation region 410 toward a central portion of the second sub-pixel 400.

The fifth isolation region 420 may be formed in a deep recess in the vertical direction to prevent a crosstalk among neighboring photodiodes and may be formed through the deep trench isolation (DTI) process.

The fifth isolation region 420 may include the same material as that of the fourth isolation region 410.

The fifth isolation region 420 may include a material having a higher refractive index than that of silicon (Si).

The fifth isolation region 420 may include at least one of a silicon oxynitride (SiON) layer, a silicon oxide (SiO) layer, a silicon nitride (SiN) layer, or polysilicon (Poly Si).

In an embodiment, the fifth isolation region 420 may include a third inner isolation region 421, and a fourth inner isolation region 422.

The third inner isolation region 421 may protrude from one region of the fourth isolation region 410 toward the central portion of the second sub-pixel 400.

The fourth inner isolation region 422 may be aligned with the third inner isolation region 421 (e.g., formed on the same straight line as the third inner isolation region 421), and may protrude from another region of the fourth isolation region 410 (a region opposite to a region in which the third inner isolation region 421 is formed) toward the central portion of the second sub-pixel 300.

In an embodiment, the third inner isolation region 421 may be formed at a position spaced apart by a certain distance from the fourth inner isolation region 422.

A sixth isolation region 430 may be formed between the third inner isolation region 421 and the fourth inner isolation region 422.

The sixth isolation region 430 may be formed in a direction orthogonal to the direction in which the third inner isolation region 421 and the fourth inner isolation region 422 are arranged.

In some implementations, one end of the sixth isolation region 430 is connected to one side of the fourth isolation region 410, and the other end of the sixth isolation region 430 is connected to an opposite side of the one side of the fourth isolation region 410.

The sixth isolation region 430 may include a material different from a material of the fifth isolation region 420.

The sixth isolation region 430 may include a material having a lower refractive index than a refractive index of silicon (Si).

In an embodiment, the sixth isolation region 430 may include an oxide.

In an embodiment, the sixth isolation region 430 may include at least one of an oxide, a nitride, or an oxynitride.

The sixth isolation region 430 may have a depth which is different from a depth of the fifth isolation region 420.

The depth of the sixth isolation region 430 may be smaller than a depth of the fifth isolation region 420.

In an embodiment, an oxide layer (not illustrated) may be formed on a sidewall of the fifth isolation region 420, and the sixth isolation region 430 may be formed to contact, or be spaced apart from the oxide layer (not illustrated) of the fifth isolation region 420.

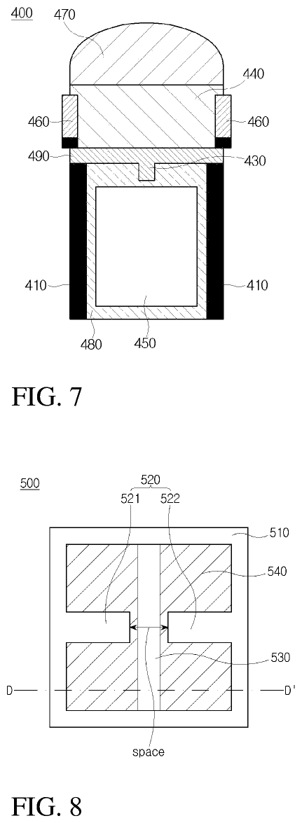

FIG. 7 is a cross-sectional view taken along line C-C′ of the second sub-pixel of FIG. 6.

Referring to FIGS. 6 and 7, the second sub-pixel 400 may include the fourth isolation region 410, the third inner isolation region 421, the fourth inner isolation region 422, the sixth isolation region 430, a red color filter 440, a photodiode 450, a filter layer isolation region 460, a microlens 470, a substrate 480, and an isolation layer 490.

The fourth isolation region 410 may be formed between neighboring sub-pixels.

The third inner isolation region 421 and the fourth inner isolation region 422 may be formed below the isolation layer 490.

In an embodiment, the sixth isolation region 430 may be formed below the isolation layer 490, and may be a region in which at least one of an oxide, a nitride, or an oxynitride is formed (e.g., deposited) in a groove in an etched region of the substrate 480. In an embodiment, the sixth isolation region 430 may be formed with a thin thickness on a surface of the substrate 480.

In an embodiment, the sixth isolation region 430 may be formed in a direction crossing (or extending) between the third inner isolation region 421 and the fourth inner isolation region 422, from one side of the fourth isolation region 410 perpendicular to the third inner isolation region 421 or the fourth inner isolation region 422. In an embodiment, the third inner isolation region 421, the fourth inner isolation region 422, and the sixth isolation region 430 may form a cross structure.

Since the sixth isolation region 430 having a thin thickness is formed in the direction crossing (or extending) between the third inner isolation region 421 and the fourth inner isolation region 422, the scattered light may be dispersed in both directions (upward and downward, and left and right directions), rather than one direction (upward and downward, or left and right directions), and accordingly the output signal (Gr/Gb) differences between the Gr pixel and the Gb pixel may be improved. In addition, the optical loss may be minimized and a Gr/Gb signal difference may be improved compared to the pixel isolation region of a cross structure (DTI). In case of the pixel isolation region of a cross structure (DTI), the optical loss may occur due to the optical absorption.

The sixth isolation region 430 of the second sub-pixel 400, which includes the red color filter 440, may be formed in a direction perpendicular to a direction in which the third isolation region 330 of the first sub-pixel 300 is formed.

The red color filter 440 may be formed over the isolation layer 490. The red color filter 440 may filter and pass the visible light out of the incident light incident on the microlens 470, and may allow only the red light out of the visible light to path through.

The photodiode 450 may be formed in an inner region of the substrate 480 and may be formed below the sixth isolation region 430, and a n-type impurity region and a p-type impurity region may be vertically stacked in the photodiode 450. The n-type impurity region and the p-type impurity region may be formed through the ion injection process.

The filter layer isolation region 460 may be formed over the fourth isolation region 410.

The microlens 470 may be formed over the red color filter 440, and may serve to collect the incident light entered from the outside.

In an embodiment, the substrate 480 may include a silicon (Si) material in a single-crystalline state.

The isolation layer 490 may be formed over the fourth isolation region 410 and the fifth isolation region 420, and may include at least one of an oxide, a nitride, or an oxynitride.

FIG. 8 is a view for describing the third sub-pixel of the pixel array based on an embodiment.

Referring to FIGS. 2 and 8, a seventh isolation region 510 may be formed in an edge region (a boundary region between the third sub-pixels 500) of the third sub-pixel 500. The seventh isolation region 510 may be formed in a deep recess in the vertical direction to prevent a crosstalk among neighboring sub-pixels and may be formed through the deep trench isolation (DTI) process.

The seventh isolation region 510 may include at least one of a silicon oxynitride (SiON) layer, a silicon oxide (SiO) layer, a silicon nitride (SiN) layer, or polysilicon (Poly Si).

An eighth isolation region 520 may be formed inside the seventh isolation region 510. The eighth isolation region 520 may be formed in a direction of a central portion of the third sub-pixel 500 from the seventh isolation region 510.

The eighth isolation region 520 may be formed in a deep recess in the vertical direction to prevent a crosstalk among neighboring photodiodes and may be formed through the deep trench isolation (DTI) process.

The eighth isolation region 520 may include the same material as that of the seventh isolation region 510.

The eighth isolation region 520 may include a material having a higher refractive index than that of silicon (Si).

The eighth isolation region 520 may include at least one of a silicon oxynitride (SiON) layer, a silicon oxide (SiO) layer, a silicon nitride (SiN) layer, or polysilicon (Poly Si).

In an embodiment, the eighth isolation region 520 may include a fifth inner isolation region 521, and a sixth inner isolation region 522.

The fifth inner isolation region 521 may protrude from one region of the seventh isolation region 510 toward the central portion of the third sub-pixel 500.

The sixth inner isolation region 522 may be aligned with the fifth inner isolation region 521 (e.g., formed on the same straight line as the fifth inner isolation region 521), and may protrude from another region of the seventh isolation region 510 (a region opposite to a region in which the fifth inner isolation region 521 is formed) toward the central portion of the third sub-pixel 500.

In an embodiment, the fifth inner isolation region 521 may be formed at a position spaced apart by a certain distance from the sixth inner isolation region 522.

A ninth isolation region 530 may be formed between the fifth inner isolation region 521 and the sixth inner isolation region 522.

The ninth isolation region 530 may be formed in a direction orthogonal between the fifth inner isolation region 521 and the sixth inner isolation region 522.

It may be configured in a way that one side of the ninth isolation region 530 contacts one side of the seventh isolation region 510, and the other side of the ninth isolation region 530 contacts the other side of the seventh isolation region 510.

The ninth isolation region 530 may include a material different from a material of the eighth isolation region 520.

The ninth isolation region 530 may include a material having a lower refractive index than a refractive index of silicon (Si).

In an embodiment, the ninth isolation region 530 may include an oxide.

In an embodiment, the ninth isolation region 530 may include at least one of an oxide, a nitride, or an oxynitride.

The ninth isolation region 530 may have a depth which is different from a depth of the eighth isolation region 520.

The depth of the ninth isolation region 530 may be smaller than a depth of the eighth isolation region 520.

In an embodiment, an oxide layer (not illustrated) may be formed on a sidewall of the eighth isolation region 520. In one example, the ninth isolation region 530 may be in contact with the oxide layer (not illustrated) of the eighth isolation region 520. In another example, the ninth isolation region 530 may be spaced apart from the oxide layer (not illustrated) of the eighth isolation region 520.

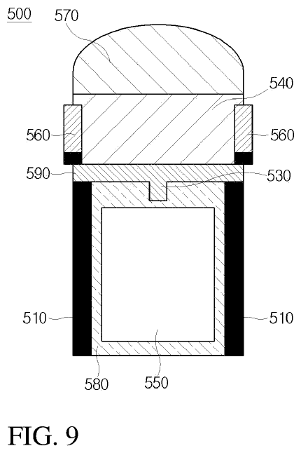

FIG. 9 is a cross-sectional view taken along line D-D′ of the third sub-pixel of FIG. 8.

Referring to FIG. 9, the third sub-pixel 500 may include the seventh isolation region 510, the fifth inner isolation region 521, the sixth inner isolation region 522, the ninth isolation region 530, a blue color filter 540, a photodiode 550, a filter layer isolation region 560, a microlens 570, a substrate 580, and an isolation layer 590.

The seventh isolation region 510 may be formed between neighboring sub-pixels.

The fifth inner isolation region 521 and the sixth inner isolation region 522 may be formed below the isolation layer 590.

In an embodiment, the ninth isolation region 530 may be formed below the isolation layer 590, and may be a region in which at least one of an oxide, a nitride, or an oxynitride is deposited in a groove in one region of the substrate 580 which has been etched. In an embodiment, the ninth isolation region 530 may be formed with a thin thickness on a surface of the substrate 580.

In an embodiment, the ninth isolation region 530 may be formed in a direction crossing (or extending) between the fifth inner isolation region 521 and the sixth inner isolation region 522, from one side of the seventh isolation region 510 perpendicular to the fifth inner isolation region 521 or the sixth inner isolation region 522. In an embodiment, the fifth inner isolation region 521, the sixth inner isolation region 522, and the ninth isolation region 530 may form a cross structure.

Since the ninth isolation region 530 having a thin thickness is formed in the direction crossing (or extending) between the fifth inner isolation region 521 and the sixth inner isolation region 522, the scattered light may be dispersed in both directions (upward and downward, and left and right directions), rather than one direction (upward and downward, or left and right directions), thereby the output signal (Gr/Gb) differences between the Gr pixel and the Gb pixel may be improved. In addition, the optical loss may be minimized and a Gr/Gb signal difference may be improved compared to that of the pixel isolation region of a cross structure (DTI). In the case of the pixel isolation region of a cross structure (DTI), the optical loss may occur due to the optical absorption.

The ninth isolation region 530 of the third sub-pixel 500, which includes the blue color filter 540, may be formed in a direction perpendicular to a direction in which the third isolation region 330 of the first sub-pixel 300, which includes the green color filter 340, is formed.

The blue color filter 540 may be formed over the isolation layer 590. The blue color filter 540 may filter and pass the visible light out of the incident light input to the microlens 570, and may allow only the blue light out of the visible light to path through.

The photodiode 550 may be formed in an inner region of the substrate 580 and may be formed below the ninth isolation region 530, and a n-type impurity region and a p-type impurity region may be vertically stacked in the photodiode 550. The n-type impurity region and the p-type impurity region may be formed through the ion injection process.

The filter layer isolation region 560 may be formed over the seventh isolation region 510.

The microlens 570 may be formed over the blue color filter 540, and may serve to collect the incident light entered from the outside.

In an embodiment, the substrate 580 may include a silicon (Si) material in a single-crystalline state.

The isolation layer 590 may be formed over the seventh isolation region 510 and the eighth isolation region 520, and may include at least one of an oxide, a nitride, or an oxynitride.

Only a few implementations and examples are described and other implementations, enhancements and variations can be made based on what is described and illustrated in this patent document.

What is claimed is:

1. An image sensing device, comprising:
a pixel array including a plurality of unit pixels,
wherein each of the unit pixels comprises a plurality of sub-pixels,
wherein a first isolation region is formed in an edge region of the plurality of sub-pixels,
wherein a second isolation region is formed from the first isolation region toward a central portion of each of the sub-pixels,
wherein the second isolation region comprises:
a first inner isolation region protruding from one region of the first isolation region toward the central portion of the sub-pixel; and
a second inner isolation region aligned with the first inner isolation region and protruding from another region of the first isolation region toward the central portion of the sub-pixel, and
wherein a third isolation region is formed in a direction orthogonal to a direction in which the first inner isolation region and the second inner isolation region.

2. The image sensing device of claim 1,
wherein each of the sub-pixels comprises:
the first isolation region;
the second isolation region comprising the first inner isolation region and the second inner isolation region;
an isolation layer formed over the first inner isolation region and the second inner isolation region;
the third isolation region formed below the isolation layer;
a color filter formed over the isolation layer; and
a microlens formed over the color filter.

3. The image sensing device of claim 1,
wherein the second inner isolation region is formed at a position spaced apart by a certain distance from the first inner isolation region.

4. The image sensing device of claim 3,
wherein the third isolation region is formed in a direction crossing between the first inner isolation region and the second inner isolation region, from one side of the first isolation region perpendicular to the first inner isolation region or the second inner isolation region.

5. The image sensing device of claim 1,
wherein the third isolation region comprises at least one of an oxide, a nitride, or an oxynitride.

6. The image sensing device of claim 1,
wherein the third isolation region comprises a material different from a material of the second isolation region.

7. The image sensing device of claim 1,
wherein the second isolation region comprises a material having a higher refractive index than a refractive index of silicon.

8. The image sensing device of claim 1,
wherein the second isolation region comprises polysilicon.

9. The image sensing device of claim 1,
wherein the third isolation region comprises a material having a lower refractive index than a refractive index of silicon.

10. The image sensing device of claim 1,
wherein a depth of the third isolation region is smaller than a depth of the second isolation region.

11. The image sensing device of claim 1,
wherein the third isolation region is in contact with the second isolation region.

12. The image sensing device of claim 1,
wherein the third isolation region is spaced apart from the second isolation region.

13. An image sensing device, comprising:
a pixel array including a plurality of unit pixels,
wherein each of the unit pixels comprises:
a first sub-pixel comprising a green color filter;
a second sub-pixel comprising a red color filter; and
a third sub-pixel comprising a blue color filter,
wherein a first isolation region is formed in an edge region of the first sub-pixel,
wherein a fourth isolation region is formed in an edge region of the second sub-pixel,
wherein a second isolation region is formed from the first isolation region toward a central portion of the first sub-pixel,
wherein a fifth isolation region is formed to protrude from the fourth isolation region in a direction perpendicular to a direction in which the second isolation region is formed,
wherein the second isolation region comprises:
a first inner isolation region protruding from one region of the first isolation region toward the central portion of the first sub-pixel; and
a second inner isolation region aligned with the first inner isolation region and protruding from another region of the first isolation region toward the central portion of the first sub-pixel,
wherein the fifth isolation region comprises:
a third inner isolation region protruding from one region of the fourth isolation region toward a central portion of the second sub-pixel; and
a fourth inner isolation region aligned with the third inner isolation region and protruding from another region of the fourth isolation region toward the central portion of the second sub-pixel,
wherein a third isolation region is formed in a direction orthogonal to a direction in which a first inner isolation region and the second inner isolation region are arranged; and
wherein a sixth isolation region is formed in a direction orthogonal to a direction in which the third inner isolation region and the fourth inner isolation region are arranged.

14. The image sensing device of claim 13,
wherein the first sub-pixel comprises:
the first isolation region;
the second isolation region comprising the first inner isolation region and the second inner isolation region;
an isolation layer formed over the first isolation region and the second isolation region;
the third isolation region formed below the isolation layer;
the green color filter formed over the isolation layer; and
a microlens formed over the green color filter.

15. The image sensing device of claim 13,
wherein the first inner isolation region is formed at a position spaced apart by a certain distance from the second inner isolation region.

16. The image sensing device of claim 15,
wherein the third isolation region is formed in a direction crossing between the first inner isolation region and the second inner isolation region, from one side of the first isolation region perpendicular to the first inner isolation region or the second inner isolation region.

17. The image sensing device of claim 13,
wherein the third isolation region comprises at least one of an oxide, a nitride, or an oxynitride.

18. The image sensing device of claim 13,
wherein the third inner isolation region is formed at a position spaced apart by a certain distance from the fourth inner isolation region.

19. The image sensing device of claim 18,
wherein the sixth isolation region is formed in a direction crossing between the third inner isolation region and the fourth inner isolation region, from one side of the fourth isolation region perpendicular to the third inner isolation region or the fourth inner isolation region.

20. The image sensing device of claim 13,
wherein a seventh isolation region is formed in an edge region of the third sub-pixel,
wherein an eighth isolation region is formed to protrude from the seventh isolation region in a direction perpendicular to the direction in which the second isolation region is formed,
wherein the eighth isolation region comprises:
a fifth inner isolation region protruding from one region of the seventh isolation region toward a central portion of the third sub-pixel; and
a sixth inner isolation region aligned with the fifth inner isolation region and protruding from another region of the seventh isolation region toward the central portion of the third sub-pixel, and
wherein a ninth isolation region is formed in a direction orthogonal to a direction in which the fifth inner isolation region and the sixth inner isolation region are arranged.
